(19) United States
(12) Patent Application Publication
(10) Pub. No.: US 2010/0301464 A1
(43) Pub. Date: Dec. 2, 2010

(54) ASTERISK PAD

(76) Inventor: Mohamad Ashraf bin Mohd Arshad, Kuala Lumpur (MY)

Correspondence Address: TEXAS INSTRUMENTS INCORPORATED, P O BOX 655474, M/S 3999, DALLAS, TX, 75265, US

(21) Appl. No.: 12/471,824

(22) Filed: May 26, 2009

(51) Int. Cl. H01L 23/495; H01L 21/60

(52) U.S. Cl. 257/676; 438/118; 257/E23.037; 257/E21.506

(57) ABSTRACT

A method and structure for a semiconductor device can include a chip support having a one or more elongated structures formed in the chip support The elongated structures, which have a width and a length greater than the width, receive chip attach material such as epoxy during a chip attach process. Because each elongated feature is oriented such that an axis through a center of the length of each elongated feature points to a center of the chip support, the chip attach adhesive flows into the feature with minimal trapping of air. Trapped air can cause delamination of the chip from the chip support, or cracking of the chip and device failure.

### FIELD OF THE INVENTION

This invention pertains to the field of semiconductor devices, and more particularly to a method and structure for attachment of a semiconductor chip to a leadframe.

### BACKGROUND OF THE INVENTION

A semiconductor device such as memory device, logic device, microprocessor, etc. can be packaged with conductive external connections to facilitate electrical coupling with test equipment, and eventual connection with a substrate such as a printed circuit board (PCB). Through-hole packages having leads which project through a printed circuit board, such as single in-line packages (SIPs) and dual in-line packages (DIPs), progressed to surface mount leads such as “j” style leads, which in turn progressed to surface mount connections such as flip chip and ball grid array (BGA) devices.

Semiconductor device package styles include various types of leadframes to which a semiconductor chip (die, wafer section, etc.) is attached. Leadframe designs can comprise a chip pad (die pad) which can have a length and width which is smaller or larger than the chip, or the same size as the chip. A noncircuit (back) side of the chip is adhered to the chip pad using a chip attach material such as a liquid adhesive, double-sided tape, thermoplastic, or thermoset material.

Another type of surface mount package is known as a quad flat no-lead (QFN) device. This package style comprises the following elements: a stamped or etched electrically conductive leadframe having a chip pad and leads adjacent to, and spaced from, the chip pad; a semiconductor chip having bond pads around a perimeter of the chip; chip attach material which adheres the back side of the chip to the chip pad; conductive bond wires which electrically couple the bond pads on the chip with the leads of the leadframe; and encapsulation material or other packaging which protects the chip and the bond wires to minimize damage resulting from physical contact and from moisture and other contamination. To support the chip and to assist with the dissipation of heat away from the chip during device operation, the leadframe chip pad is typically the same size and shape as the chip or larger to function as a heat sink subsequent to the attachment of the chip. After completion of device packaging, a portion of the lower surface of the leadframe, including the chip pad and the external leads, are flush with the encapsulation material and are therefore exposed. In addition to providing a heat sink to dissipate heat from the operating chip, the chip pad can provide a “power pad” which can function as a path to ground for the semiconductor chip using a conductive chip attach material.

Regardless of the type of surface mount package, the wafer section, such as a semiconductor chip or die which has been singularized from a semiconductor wafer during a wafer dicing process, is attached to a supporting structure. As discussed above, devices which include a leadframe can comprise a chip attach tape, which can include a supporting polyimide carrier having a thermoset adhesive on either side. In other devices, a die can be attached to the chip pad using a flowable material such as a thermoset or thermoplastic, or another adhesive material such as epoxy adhesive.

Attachment of a chip to a chip pad using a chip attach tape comprising a thermoset material can include holding the chip, the chip pad, and the chip attach material in fixed relative position while the thermoset is cured. The use of chip attach tape is a proven, but relatively expensive, die attachment method.

The use of liquid adhesives to attach a semiconductor chip to a chip pad comprises dispensing the liquid adhesive onto the chip pad, then placement of the chip into the adhesive. A “scrub” is often used to ensure good physical contact between the adhesive and the chip. Further, the chip is typically placed into the adhesive using a controlled pressure to ensure that a space between the chip and the chip pad (the “bond line”) is within a desired range and an even thickness. Once contact between the chip and the adhesive is made, the adhesive is cured, typically using elevated temperatures.

When using epoxy, the chip pad can be partially etched at a location close to the perimeter of the chip pad to form a plurality of hemispherical or circular “dimples.” During chip attach, the epoxy is dispensed onto the pad and the chip is placed into the epoxy, and a controlled opposing force is applied between the chip and chip pad. This results in a flow of epoxy over and into the dimples. The dimples serve to increase material interface interlock and, once the epoxy is cured, the epoxy within the dimples helps to stabilize the position of the chip relative to the chip pad.

### SUMMARY OF THE EMBODIMENTS

Attachment of a semiconductor chip to a chip pad using epoxy can have advantages over using chip attach tape. For example, in some semiconductor manufacturing processes, attachment of a chip to a chip pad with epoxy can be a simpler process requiring less expensive materials over a process which uses chip attach tape.

In contemplating the assembly of semiconductor devices, particularly the attachment of a chip to a chip pad, the inventor has realized that even though a chip pad having dimples can have advantages, epoxy voiding can result from the use of a such a chip pad. As previously discussed, dimples can be formed in an attempt to stabilize the position of the chip relative to the chip pad. During assembly, an amount of epoxy is dispensed onto the chip pad and the chip is placed into the epoxy with a controlled force. After examining a cross sectioned device having a hemispherical dimple, the inventor observed voids in the epoxy. It was determined that as the epoxy flows across the chip pad and into the hemispherical-shaped dimples, air can become trapped in the dimple between the chip pad and the epoxy, or within the epoxy. It is believed that the hemispherical shape of the dimples does not lend itself to the smooth flow of epoxy into the dimple, and that the epoxy can flow over the top of the dimple without completely filling it, resulting in trapped air. Then, after the epoxy is cured, the trapped air can expand during heating of the chip, for example during device packaging or device use, which can loosen or dislodge (delaminate) the chip from the chip pad, resulting in a loose or cracked chip or other device failures.

After realizing this possible source of epoxy voiding and device unreliability or failure, the inventor has developed a new semiconductor device design which, in one embodiment, comprises an etched leadframe chip pad. In an embodiment, one or more elongated features such as elongated grooves and/or dimples are etched into the chip pad which are oriented in a direction of the flow of epoxy across the chip pad as the chip is placed into the adhesive. The particular groove profile and orientation on the chip pad can reduce or eliminate air trapped within the dimple, and provide a more reliable device design.

In contrast with conventional hemispherical dimples, and without being limited by theory, it is believed that the elongated structure of the features oriented in the direction of the flow of epoxy across the chip pad allows chip attach adhesive to more easily flow into it. This results in a more complete filling of the elongated features compared to conventional hemispherical dimples. More complete filling of the elongated grooves and/or dimples is believed to reduce or eliminate air pockets trapped in the adhesive by easing its flow into the features. Thus a semiconductor device and method in accordance with various embodiments of the invention has a more reliable attachment of the chip to the chip pad, increased resistance to loosening of the chip from the chip pad, decreased occurrence of chip cracks, and improved reliability.

These and other technical advances represented by the inventor's device design, as well as the aspects thereof, will become apparent from the following description of the preferred embodiments of the invention, when considered in conjunction with the accompanying drawings and the novel features set forth in the appended claims.

### BRIEF DESCRIPTION OF THE DRAWINGS

The accompanying drawings, which are incorporated in and constitute a part of this specification, illustrate embodiments of the invention and together with the description, serve to explain the principles of the invention. In the figures:

FIG. 1 is a plan view of a portion of a leadframe which can be used with embodiments of the invention comprising leads and a chip pad;

FIG. 2 is a conventional chip pad having hemispherical dimples etched into a perimeter of the chip pad;

FIG. 3 is a side view of the FIG. 2 chip pad;

FIG. 4 is a plan view of a chip pad having an arrangement of elongated dimples etched into a perimeter of the chip pad;

FIG. 5 is a plan view of the FIG. 4 chip pad depicting the direction of flow of a chip attach adhesive across a surface of the chip pad;

FIG. 6 is a plan view of a chip pad having an arrangement of grooves and dimples etched into the chip pad, and a remaining center chip support;

FIG. 7 is a plan view of a chip pad having another arrangement of grooves etched into the chip pad;

FIG. 8 is a perspective cut-away view of an encapsulated semiconductor device;

FIG. 9 is a cross section depicting an attachment of a chip to a chip pad having a hemispherical dimple;

FIG. 10 depicts the FIG. 9 structure after completing attachment of the chip to the chip pad;

FIGS. 11-13 are cross sections depicting attachment of a chip to a chip pad having an elongated dimple, and a resulting bond line;

FIG. 14 is a plan view of a chip pad having another arrangement of grooves etched into the chip pad; and

FIG. 15 is a plan view of a chip pad having a perimeter with a jagged or irregular edge.

It should be noted that some details of the FIGS. may have been simplified and are drawn to facilitate understanding of the inventive embodiments rather than to maintain strict structural accuracy, detail, and scale.

### DESCRIPTION OF THE EMBODIMENTS

Reference will now be made in detail to the present embodiments (exemplary embodiments) of the invention, example of which are illustrated in the accompanying drawings. Wherever possible, the same reference numbers will be used throughout the drawings to refer to the same or like parts.

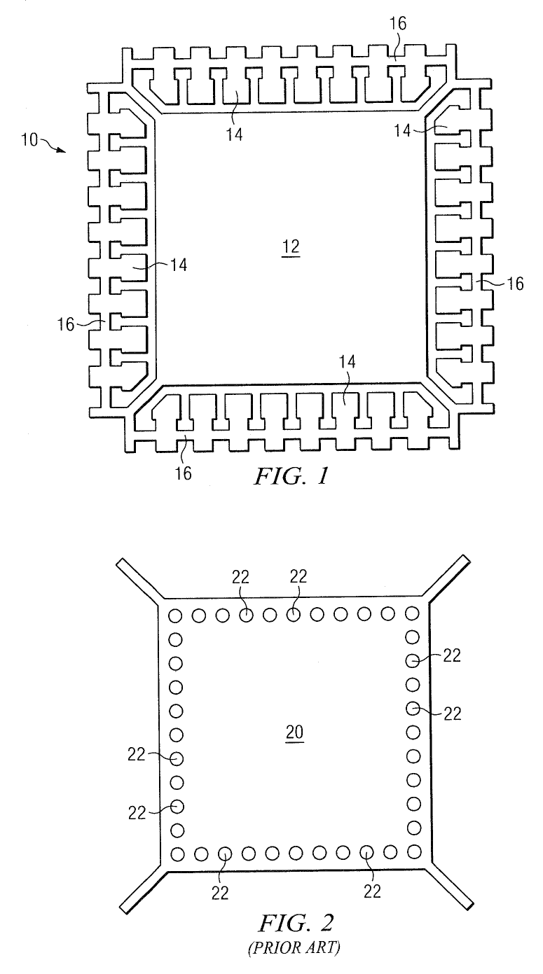

FIG. 1 depicts a portion of a leadframe 10 comprising a chip pad 12, segments 14 which can receive a bond wire after a subsequent attachment of a chip to the chip pad 12, and dam bars 16 provide functionality during package encapsulation. In the depicted embodiments, the leadframe is a quad flat no-lead (QFN) style package, but it will be appreciated that other leadframe styles can also benefit from various embodiments of the invention. The QFN package typically comprises a relatively small chip, and therefore the area of attachment between the chip and the chip pad is correspondingly small. Thus a void in the chip attachment material can severely weaken the attachment of a chip to the chip pad.

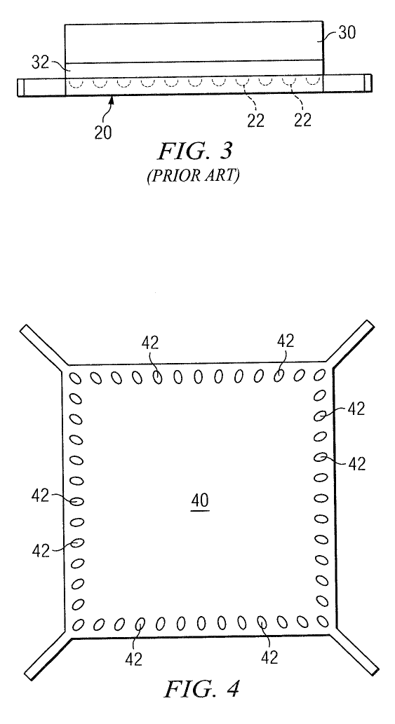

FIG. 2 is a plan view, and FIG. 3 is a side view, of a chip pad 20 comprising hemispherical dimples 22 which are etched into the leadframe chip pad. FIG. 3 also depicts an attached semiconductor chip 30 and chip attach adhesive 32 such as epoxy. As described in previous sections, the hemispherical dimples can increase stability of the chip relative to the chip pad, particularly in a lateral direction. However, the inventor has realized that as epoxy flows over the hemispherical dimples, air can become trapped in the epoxy. After attaching a chip with epoxy and curing the epoxy, the air can expand during encapsulation, testing, or operation, which can crack the chip or dislodge it from the chip pad, resulting in device unreliability or failure.

As used herein, the term “elongated feature” refers to a feature such as a dimple, groove, channel, etc. which can be etched, stamped, laser ablated, etc. into a chip support such as a chip pad, ceramic chip support, resin chip support, etc.

FIG. 4 depicts a plurality of elongated features comprising a dimple design on a chip pad 40 in which a plurality of individual, discontinuous etched dimples 42 are each formed to be elongated. In the FIG. 4 structure, each of the plurality of elongated features is ½ etched (i.e. ½ the thickness of the chip pad is etched) and located around a perimeter of the chip support 40.

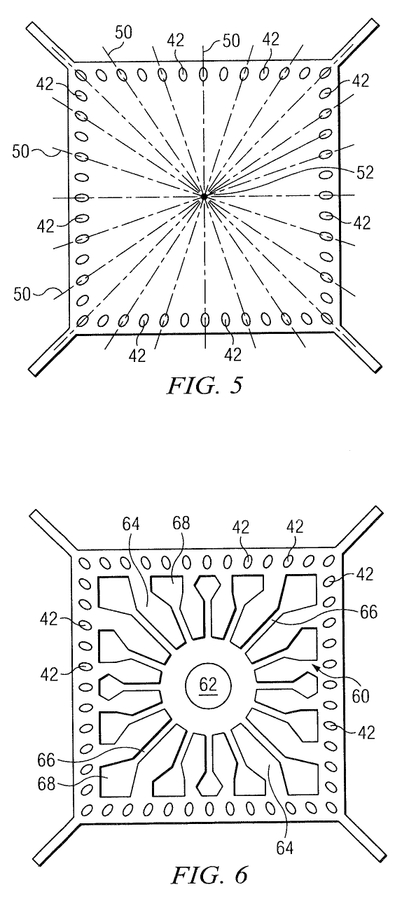

Without being limited by theory, it is believed that such a design can allow a chip attach material to more easily flow into the dimples so that trapped air is reduced or eliminated. In addition to being elongated, the direction of the elongation is formed in line with a direction of flow of the adhesive as it moves across the chip pad. FIG. 5 depicts the FIG. 4 structure and specifies an axis 50 for each feature. Each axis is formed parallel to a directionality of adhesive flow for an epoxy dispensed at the center 52 of the chip pad. As depicted, each dimple 42 has a width and a length longer than the width. Each elongated feature 42 is oriented such that the axis 50 through a center of the length of each elongated feature extends through (points to) the center 52 of the chip support. The directionality of the elongation for each individual dimple is aligned with the directionality of the flow of adhesive across the pad. As the adhesive flows outward radially from the center of the chip pad, it flows into each dimple and along the length of the dimple.

Sufficient chip attach material is dispensed and sufficient force is applied between the chip and leadframe to provide for a desired bond line. As depicted in FIG. 5, the plurality of dimples along one edge of the chip pad can all be oriented in different directions. For example, if the center dimple along the top edge (as depicted) is considered to be oriented at 0°, the leftmost dimple in the top row is oriented at −45° and the rightmost dimple is oriented at 45°. Each dimple along an edge of the chip pad is oriented in a different direction, with its orientation depending on its location on the edge of the chip pad.

During chip attach, the dimples can also function as a reservoir to receive excess chip attach material so that surplus material is contained. This can reduce problems resulting from excess material, such as material buildup at future wire bond locations on the leadframe.

FIG. 6 depicts another embodiment comprising dimples 42 similar to those of FIG. 4, and also includes a larger etched area 60 having an “asterisk” shape for receiving the chip attach adhesive as it flows across the surface of the chip pad. Additionally, this embodiment includes a center chip pad portion 62 and an outer chip pad portion 64, both of which are not etched. The center chip pad portion 62 and outer chip pad portion 64 can serve as a chip support to enable consistent z-height control.

During assembly, a quantity of chip attach adhesive can be dispensed on the center chip pad portion 62, the a chip is placed into the adhesive. A controlled, opposing force is applied between the chip and the leadframe sufficient to flow the adhesive across the surface of the chip pad. As the adhesive flows, it enters the etched portion 60. The etched portion 60 comprises a plurality of channels or grooves 66 having a directionality which is parallel to the radial flow of adhesive away from the center chip pad portion 62, similar to that depicted at 50 in FIG. 5. The etched portion 60 receives the chip attach material as it flows across the chip pad. End portions 68 can receive a large quantity of chip attach adhesive (epoxy mass) to prevent excess material from extruding from under the chip an onto other leadframe structures. The center pad portion 62 supports the center of the chip (not depicted), for example during attachment of the chip to the chip pad.

With conventional devices, it has been difficult to control the z-height of the chip and include a sufficient mass of chip attach adhesive. Z-height control ensures that a plane of the circuit side of the chip is parallel to a plane of the chip pad surface so that wire bonding problems are reduced. However, to ensure the two surface planes are parallel often required an excessively thin quantity of chip attach adhesive, and thus a small bond line. With the FIG. 6 structure, however, the ½ etched portion 60 allows a larger quantity of chip attach adhesive to be placed between the chip and the chip pad, while the unetched center pad 62 and outer portion 64 allow for z-height control of the chip.

The shape of the etched portion, specifically the alignment of the channels 66 in a direction parallel to the radial flow of adhesive across the chip pad, helps to reduce or eliminate voids within the epoxy. The concave shape of etched portions 60 and 42 help stabilize the attachment of the chip on the chip pad.

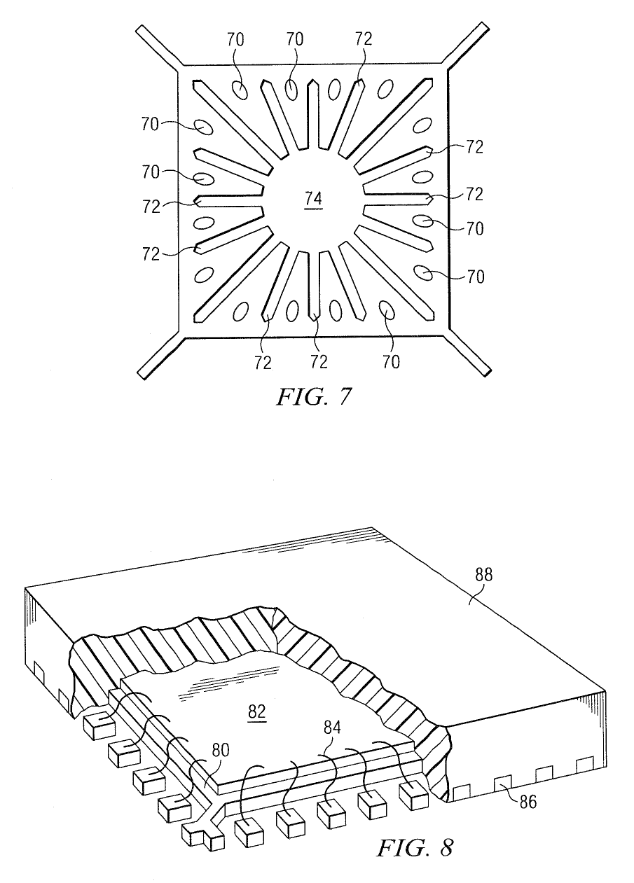

FIG. 7 depicts another embodiment comprising etched dimples 70 interposed between etched channels 72 of a large, etched region 74 on a chip pad. In this embodiment, no center pad portion such as 62 depicted in FIG. 6, although it will be appreciated that the FIG. 7 embodiment can be formed to have a center pad, if desired.

The channels 72 are formed such that each channel is oriented in a direction which is parallel with a direction of flow of a chip attach adhesive dispensed on the center of the chip pad during a chip attach step.

For example, an amount of liquid chip attach adhesive is dispensed onto the center of the chip pad, then a chip is placed into the adhesive. A controlled, opposing force is applied to the chip and the lead frame to evenly flow the epoxy across the chip pad and under the chip.

FIG. 8 is a perspective cut-away view of a completed QFN semiconductor device. The FIG. 8 device comprises a chip pad 80, a semiconductor chip 82 such as one or more singularized or unsingularized wafer sections, bond wires 84, leadframe portions 86 to facilitate electrical coupling of circuitry (not individually depicted) on the circuit side of the chip 82 with an external device, and encapsulation material 88.

In various uses, the one or more elongated features can be formed in chip supports other than the chip pad described. Other chip supports include other metal and ceramic chip supports, silicon chip supports, resin chip supports, etc. Further, the dimples, grooves, and channels can be formed by techniques other than etching, such as by stamping, laser ablation, molding during formation of the support, etc.

It will be appreciated that various embodiments of the invention, for example elongated features formed in the chip pad, can reduce or eliminate voids or air pockets trapped inside of the package, for example formed within the chip attach adhesive. Without being limited by theory, this may result from an improved flow of adhesive into an elongated feature having an axis formed parallel to the direction of a flow of adhesive across the chip pad. Because small device packages such as QFN devices are particularly sensitive to void defects, the invention allows for the use of epoxy for chip attach with packages comprising a small chip. However, other package types can also benefit from the described or other embodiments of the invention. In previous packages, chip attach tape was required to ensure a reliable attachment of a semiconductor chip to a chip pad of a leadframe. Further, various embodiments of the invention can allow for improved control of a liquid chip attach adhesive bond line as discussed above.

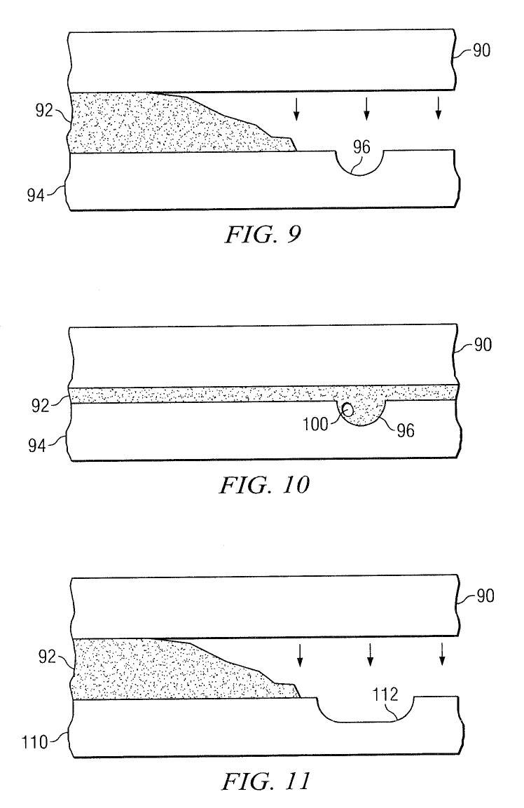

FIGS. 9 and 10 are cross sections depicting the placement of a die 90 into an epoxy 92 which has been dispensed onto a leadframe 94 having a conventional hemispherical dimple 96. In this example, a force is applied to the die 90 in a direction toward the leadframe 94. The applied force thins the epoxy 92, and the epoxy travels into and over the hemispherical dimple 96 over a period of time. The speed of the epoxy across the dimple results in a void 100 (an air bubble) in the epoxy, which can result in the problems previously described.

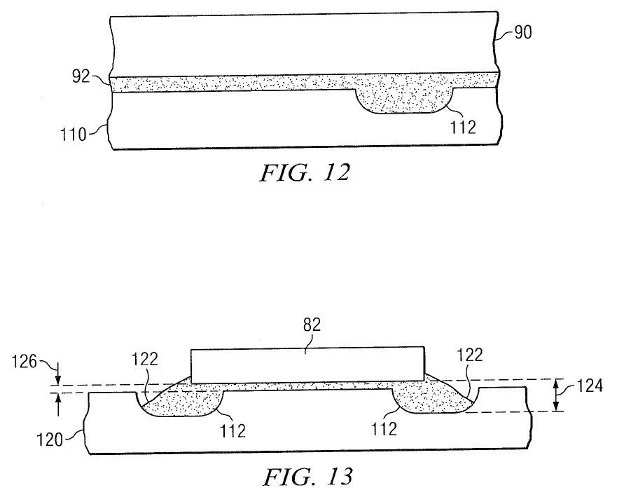

As depicted in FIGS. 11 and 12, the leadframe 110 comprises an elongated dimple or channel 112. As the die 90 is forced into the epoxy 92, the epoxy travels into and over the elongated dimple or channel over a period of time. The epoxy 92 takes longer to travel over the elongated dimple 112 than it does over the hemispherical dimple 96, and the epoxy fills the elongated 112 more efficiently than it fills the hemispherical dimple 96, resulting in less voiding.

Additionally, a minimum epoxy bond line thickness (BLT) is required to attain good reliability of the die attach. However, with relatively smaller dies, a thicker bond line can produce a higher die tilt of the die on the die pad which can result in wire bond process problems. While a thinner bond line decreases die tilt, it compromises on reliability due to the decreased mass of die attach adhesive between the die and the die pad. One function of epoxy is to absorb stresses inducted between the die and the die pad. To maintain a sufficient amount of material between the die and the leadframe and minimize die tilt, chip attach tape can be used. However, a liquid adhesive such as an epoxy is a less expensive process than chip attach through the use of chip attach tape. An embodiment of the invention can increase the amount of epoxy between the die and the leadframe while reducing die tilt. For example, FIG. 13 depicts a die 82, an epoxy 122, and a leadframe die pad having an elongated dimple. As depicted, a first thickness 124 of epoxy 122 under edges of the die 82 is greater than a second thickness 126 of epoxy 122 under a center portion of the die. The elongated grooves increase epoxy loading at the edges of the die while maintaining some “landing” and thinner epoxy to resolve die tilt.

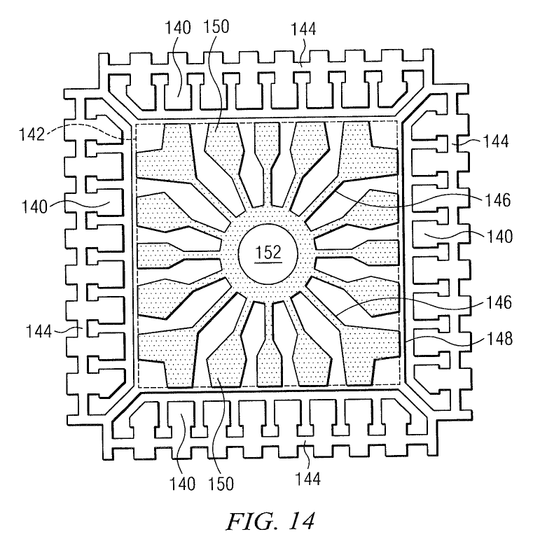

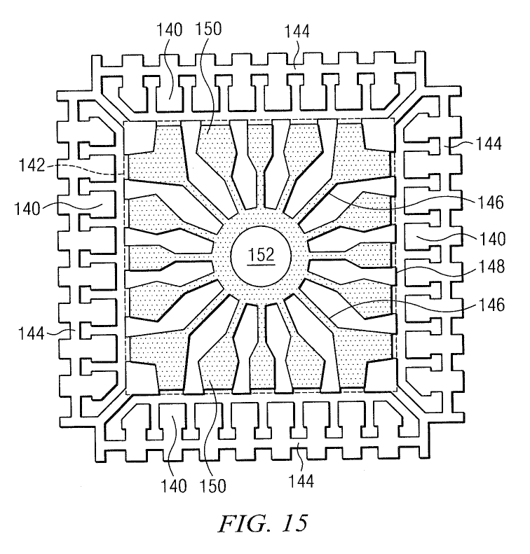

FIG. 14 is a plan view depicting an embodiment of the invention comprising segments 140 which can receive a bond wire after a subsequent attachment of a chip 142, dam bars 144, etched grooves or channels 146 in the die pad 148, and end portions 150 which can receive a quantity of chip attach material as it flows across the chip pad 148. FIG. 14 further comprises a center pad 152 which can support the center of the chip 142, during and subsequent to its attachment to the die pad 148. This embodiment does not include elongated dimples, although a dimpled embodiment is also contemplated.

FIG. 15 is a plan view depicting an embodiment of the invention comprising a chip support in the form of a die pad having a perimeter with at least one jagged or irregular edge. In this embodiment, the perimeter of the die pad has four edges, with each of the four edges having a jagged or irregular profile. The perimeter of the die can be even with, or overlap, the outside perimeter of the die pad. The jagged or irregular edges of the die pad can result in reduced stress at the perimeter of the die. For example, the depicted structure can more evenly distribute stresses resulting from thermal mismatch of the die and the die pad during heating and cooling of the structures than a conventional die pad with straight edges. A die pad structure similar to that depicted can reduce damage and other stress-related effects to the die. The structure of FIG. 15 includes a plurality of square or rectangular cutouts from each edge of the die pad.

Advantages of epoxy over chip attach tape other than cost are known. Current chip attach tape processing includes mounting of full wafers at once on the die attach tape, then dicing of the wafer. Without this mounting, the wafer could be halved or quartered to mount only a required number of dies, with the remainder kept for use as needed. With epoxy, the chips are mounted to the lead frame as needed. Further, mounting a full wafer on chip attach tape is also limited by the shelf life of the tape, which is relatively short. Again, using epoxy, the dies are mounted as needed. Additionally, a chip tape process is performed prior to full testing of the dies, and thus if the wafer has a high percentage of failed dies, the high cost of mounting can become more expensive. With epoxy mounting, each die is mounted after testing, thus only known good die are mounted to a leadframe.

Additionally, the use of epoxy enables a higher thermal performance over the use of chip attach tape. Current standard epoxy has a higher thermal conductivity index compared to chip attach tape, which improves the dissipation of heat away from the die to the die pad. In the case of a QFN device, epoxy would provide for improved heat dissipation away from the die to the die pad, then to the supporting substrate such as a printed circuit board.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5. In certain cases, the numerical values as stated for the parameter can take on negative values. In this case, the example value of range stated as “less that 10” can assume negative values, e.g. −1, −2, −3, −10, −20, −30, etc.

While the invention has been illustrated with respect to one or more implementations, alterations and/or modifications can be made to the illustrated examples without departing from the spirit and scope of the appended claims. In addition, while a particular feature of the invention may have been disclosed with respect to only one of several implementations, such feature may be combined with one or more other features of the other implementations as may be desired and advantageous for any given or particular function. Furthermore, to the extent that the terms “including,” “includes,” “having,” “has,” “with,” or variants thereof are used in either the detailed description and the claims, such terms are intended to be inclusive in a manner similar to the term “comprising.” The term “at least one of” is used to mean one or more of the listed items can be selected. Further, in the discussion and claims herein, the term “on” used with respect to two materials, one “on” the other, means at least some contact between the materials, while “over” means the materials are in proximity, but possibly with one or more additional intervening materials such that contact is possible but not required. Neither “on” nor “over” implies any directionality as used herein. The term “conformal” describes a coating material in which angles of the underlying material are preserved by the conformal material. The term “about” indicates that the value listed may be somewhat altered, as long as the alteration does not result in nonconformance of the process or structure to the illustrated embodiment. Finally, “exemplary” indicates the description is used as an example, rather than implying that it is an ideal. Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

1-7. (canceled)

8. A semiconductor device comprising:
a semiconductor chip;
a leadframe comprising a chip pad, wherein the chip pad comprises:
a surface;
a center; and
an elongated feature located in the surface of the chip pad, wherein:
the elongated feature comprises a length and a width;
the length is longer than the width; and
the elongated feature is oriented such that an axis through a center of the length of the elongated feature extends through the center of the chip pad; and
chip attach adhesive interposed between the chip and the chip pad, and within the elongated feature.

9. The semiconductor device of claim 8 further comprising a plurality of elongated features located in the surface of the chip pad, wherein:
each of the plurality of elongated features comprises a length and a width, with the length being longer than the width; and
each of the plurality of elongated features is oriented such that an axis through a center of the length of each elongated feature extends through the center of the chip pad.

10. The semiconductor device of claim 9, wherein each of the plurality of elongated features is located around a perimeter of the chip pad.

11. The semiconductor device of claim 9, further comprising each of the plurality of elongated features being interconnected by an etched chip pad portion located in the surface of the chip pad.

12. The semiconductor device of claim 11 further comprising an unetched center chip pad portion at the center of the chip pad.

13. The semiconductor device of claim 11 further comprising a plurality of elongated, individual dimples etched into the surface of the chip pad, wherein:
each dimple comprises a length and a width;
the length of each dimple is longer than the width of each dimple; and
each dimple is oriented such that a an axis through a center of the length of each elongated dimple extends through the center of the chip pad.

14. A method for forming a semiconductor device, comprising:
dispensing a quantity of chip attach adhesive onto a center of a chip support; placing a semiconductor chip into the chip attach adhesive;
applying an opposing force between the chip and the chip support, wherein during the application of the opposing force, the chip attach adhesive flows into an elongated feature located in a surface of the chip support, the elongated feature having a width and a length longer than the width, and the elongated feature being oriented such that an axis through a center of the length of the elongated feature points to the center of the chip support.

15. The method of claim 14 wherein, during the application of the opposing force, the chip attach adhesive flows into a plurality of elongated features each comprising a length and a width, with the length being longer than the width, and each of the plurality of elongated features being oriented such that an axis through a center of the length of each elongated feature points to the center of the chip support.

16. The method of claim 14, further comprising dispensing the quantity of chip attach adhesive onto the center of the chip support, wherein a perimeter of the chip support comprises four edges, wherein each edge comprises a plurality of square or rectangular cutouts.

17. A semiconductor device comprising:
a semiconductor chip affixed to a surface of a chip support; wherein the chip support includes a first plurality of elongated features disposed on the chip support; and
each elongated feature having a width, a length that is greater than the width, and a depth extending inwardly from the surface of the chip support and which increases gradually from an edge at the chip support surface towards an interior of the elongated feature; and
a chip attach adhesive between the semiconductor chip and the chip support, and in each elongated feature.

18. The semiconductor device of claim 17, in which the first plurality of elongated features are connected by a center portion of the chip support.

19. The semiconductor device of claim 18, further comprising a second plurality of elongated features disposed between the first plurality of elongated features.

20. The semiconductor of claim 18, in which the first plurality of elongated features are arranged in a radial fashion outwardly from the center portion of the chip support.

21. The semiconductor device of claim 19, in which the second plurality of elongated features have oblong shape.
